(19) United States
(12) Patent Application Publication
(10) Pub. No.: US 2007/0074653 A1
(43) Pub. Date: Apr. 5, 2007

(54) Apparatus for preparation of silicon crystals with reduced metal content

(75) Inventors: Hariprasad Sreedharamurthy, St. Peters, MO (US); John Davis Holder, St. Peters, MO (US); Mohsen Banan, St. Peters, MO (US)

Correspondence Address: SENNIGER POWERS, ONE METROPOLITAN SQUARE, 16TH FLOOR, ST LOUIS, MO, 63102, US

(73) Assignee: MEMC Electronic Materials, Inc., St. Peters, MO (US)

(21) Appl. No.: 11/241,413

(22) Filed: Sep. 30, 2005

(51) Int. Cl. C30B 35/00; C30B 27/02; C30B 15/00; C30B 21/06; C30B 28/10; C30B 30/04

(52) U.S. Cl. 117/213

(57) ABSTRACT

A crystal pulling apparatus for producing a silicon crystal ingot having a reduced amount of metal contamination. The apparatus includes a growth chamber and a component disposed within the growth chamber having a protective layer of silicon nitride for preventing metal contamination of the crystal.

### BACKGROUND OF THE INVENTION

The present invention relates generally to an apparatus for the preparation of single silicon crystals having a reduced level of contamination. More specifically, the present invention relates to an apparatus for the preparation of single silicon crystals wherein a graphite component in a crystal growth chamber of a Czochralski crystal pulling apparatus has been coated with a protective layer of silicon nitride.

Single crystal material having a monocrystalline structure, which is the starting material for fabricating many electronic components such as semiconductor devices and solar cells, is commonly prepared using the Czochralski (“Cz”) method. Briefly described, the Czochralski method involves melting polycrystalline source material such as granular or chunk polycrystalline silicon (“polysilicon”) in a quartz crucible located in a specially designed furnace to form a silicon melt. An inert gas such as argon is typically circulated through the furnace. A relatively small seed crystal is mounted above the crucible on a pulling shaft which can raise or lower the seed crystal. The crucible is rotated and the seed crystal is lowered into contact with the molten silicon in the crucible. When the seed begins to melt, it is slowly withdrawn from the molten silicon and starts to grow, drawing silicon from the melt having a monocrystalline structure.

The crystal pulling apparatus commonly utilized in the Czochralski process contains numerous internal parts surrounding the molten silicon containing crucible. These internal parts are constructed of graphite and generally referred to as “hot zone” parts. These hot zone parts, such as susceptors, heaters, thermal shields, heat reflectors and insulation, control the heat flow around the crucible and the cooling rate of the growing crystal. It has been recognized in the art that although the graphite components used in the crystal pulling apparatus are not in direct contact with the molten silicon or the growing crystal, the use of such components at the high temperatures necessary to melt the polysilicon and grow the resulting crystal can result in the outgassing of particles and resulting high level contamination of the melt and subsequently the grown crystal with molybdenum, iron, copper, nickel, and other unwanted contaminants. It is well known that metals such as iron and molybdenum reduce minority carrier lifetimes in silicon wafers and copper and nickel can lead to oxygen induced stacking faults in the resulting crystal.

In order to reduce the risk of crystal contamination with contaminants which can be outgassed by graphite parts located around the growing crystal, it has been common for all graphite components contained in the hot zone to be coated with a protective barrier layer such as silicon carbide or a glassy carbon coating. Because of its high temperature oxidation resistance, silicon carbide is widely used to coat graphite parts used in the hot zone of a crystal pulling apparatus. Silicon carbide coatings provide a barrier to impurity outgassing by sealing the graphite surface, thus requiring impurities to pass through the coating by grain boundary and bulk diffusion mechanisms. This coating is used to contain unwanted contaminants that are generated by the graphite during the crystal pulling process.

Furthermore, it is known to provide a structural component of a crystal pulling apparatus with two protective layers. The first protective layer is silicon carbide or glassy carbon and the second protective layer overlaying the first layer is silicon. The silicon protective layer provides a protective chemical barrier that acts as a gettering sink to getter contaminants from the graphite component which are able to pass through the first protective layer and contaminant which are generated from the first protective layer. Such a dual layer protective coating is disclosed in U.S. Pat. No. 6,183,553, which is incorporated herein by reference.

Although the use of prior art coatings on structural components in the hot zone of the crystal puller has reduced the amount of undesirable contaminants entering the silicon melt and/or the grown crystal, a need still exists for reduced particulate generation in the crystal puller. Particularly, undesirable metal contamination from graphite remains a prominent problem even with the use of prior art protective coatings. Undesirable metals such as iron appear able to penetrate these coatings in an amount sufficient to degrade the resulting crystal.

U.S. Pat. No. 4,090,851, which is incorporated herein by reference, discloses the use of a silicon nitride coating to protect a graphite crucible and die members used in a ribbon growth method of manufacturing semiconductor ribbon. The silicon nitride coating disclosed in the '851 patent prevents a chemical reaction between the molten silicon in the crystal puller and the graphite crucible and die member. In the '851 patent, silicon nitride is recognized as being a suitable protective coating that is chemically inert and stable when in contact with the molten silicon and is used to extend the life of the crucible and other graphite parts of the puller that are in contact with the molten silicon. The '851 patent, does not recognize the need to coat graphite hot zone components of a Czochralski crystal puller that are free from contact with molten silicon with silicon nitride to prevent outgassing of metal contaminates from the components and thereby improve the quality of the ingot formed therein.

### SUMMARY OF THE INVENTION

In general, one aspect of the invention is directed to a crystal pulling apparatus for producing a silicon crystal having a reduced amount of metal contamination. The apparatus comprises a growth chamber and a component disposed within the growth chamber having a protective layer of silicon nitride for preventing metal contamination of the crystal.

In another aspect of the invention, a component for use in a single crystal forming apparatus is provided. The component comprises a structure made of graphite and configured for reception in the single crystal forming apparatus in a location where the structure will not contact molten silicon. The component has a protective layer of silicon nitride covering the structure to inhibit out diffusion of metal.

Various refinements exist of the features noted in relation to the above-mentioned aspects of the present invention. Further features may also be incorporated in the above-mentioned aspects of the present invention as well. These refinements and additional features may exist individually or in any combination. For instance, various features discussed below in relation to any of the illustrated embodiments of the present invention may be incorporated into any of the above-described aspects of the present invention, alone or in any combination.

### BRIEF DESCRIPTION OF THE DRAWINGS

FIG. 1 is a schematic of a single crystal pulling apparatus having a structural component with a protective coating of a first embodiment;

FIG. 2 is a enlarged fragmentary section view of structural component of the first embodiment;

FIG. 3 is a view similar to FIG. 2 but showing a structural component of a second embodiment; and

FIG. 4 is a graph showing data obtained in an experiment described herein;

Corresponding parts are designated by corresponding reference numbers throughout the drawings.

### DESCRIPTION OF PREFERRED EMBODIMENTS

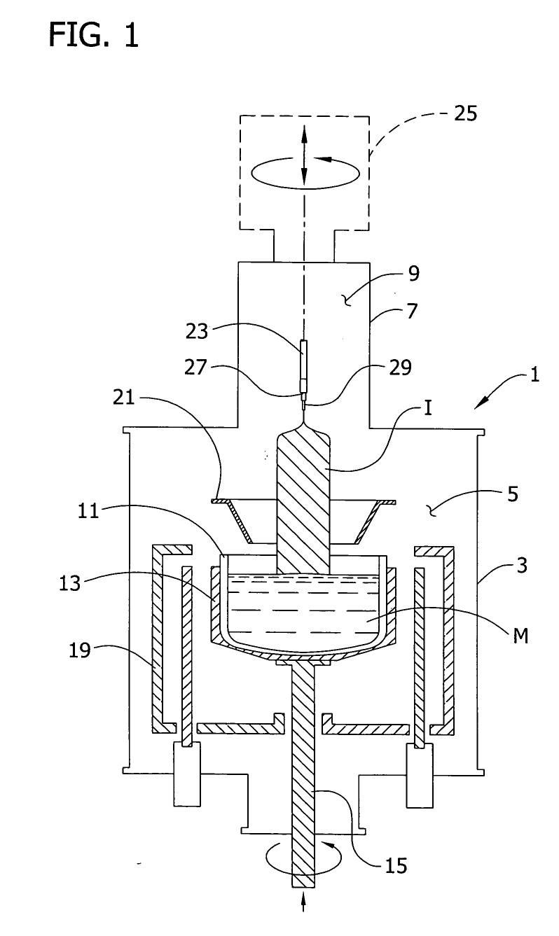

Referring to FIG. 1, a crystal pulling apparatus of one embodiment indicated generally at 1 is shown. The crystal pulling apparatus has a lower housing 3 enclosing a crystal growth chamber 5 and an upper housing 7 enclosing an upper pull chamber 9. The lower housing 3 enclosing the crystal growth chamber 5 houses a crystal growth crucible 11 seated in a susceptor 13. The crucible is suitably made of quartz and the susceptor of graphite, though other materials are contemplated. The crucible 11 contains molten source material M from which the monocrystalline silicon ingot I is grown. The susceptor 13 is mounted on a turntable 15 for rotation of the susceptor and crucible 11 about a central longitudinal axis of the crystal puller 1. The crucible 11 is also capable of being raised within the growth chamber 5 to maintain the surface of the molten source material M at a generally constant level as the ingot I is grown and source material is removed from the melt.

An electrical resistance heater 19 surrounds the crucible 11 for heating the crucible to maintain the source material M in a molten state. The heater 19 may be controlled by an external control system (not shown) so that the temperature of the molten source material M is precisely controlled throughout the pulling process. A heat shield assembly 21 optionally mounted in the growth chamber 5 above the molten source material M has a central opening sized and shaped to surround the ingot I as the ingot is pulled up from the source material. The area in the lower housing 3 surrounding the crystal growth crucible 11 is generally referred to as the “hot zone” of the puller 1. The hot zone parts include the susceptor 13, heater 19, heat shield assembly 21, and heat reflectors or insulation (not shown) that control the heat transfer around the crucible 11 and the cooling rate of the growing ingot I.

A pull shaft 23 extends down from a pulling mechanism 25 capable of raising, lowering and rotating the pull shaft. The crystal puller 1 may have a pull wire (not shown) rather than a shaft 23, depending upon the type of puller. The pull shaft 23 extends downward through the pull chamber 9 and terminates in a seed crystal chuck 27 which holds a seed crystal 29 used to grow the monocrystalline ingot I. The pull shaft 23 has been mostly broken away in FIG. 1 at its top. In growing the ingot I, the pulling mechanism 25 lowers the seed crystal 29 until it contacts the surface of the molten source material M. Once the seed crystal 29 begins to melt, the pulling mechanism 25 slowly raises the seed crystal up through the growth chamber 5 and pull chamber 9 to grow the monocrystalline ingot I. The speed at which the pulling mechanism 25 rotates the seed crystal 29 and the speed at which the pulling mechanism raises the seed crystal are suitably controlled by the external control system (not shown).

Graphite utilized to construct the hot zone components (including without limitation susceptor 13, heater 19, heat shield 21, heat reflectors and insulation) is generally at least about 99.9% pure graphite, and in one embodiment at least about 99.99% or more pure graphite. Also, the graphite suitably contains less than about 20 ppm total metals such as iron, molybdenum, copper, and nickel, and in one embodiment less than about 5 ppm total metals such as iron, molybdenum, copper, and nickel. Generally, as the purity of graphite increases, the amount of metal particle generation during high temperature heating of the component decreases.

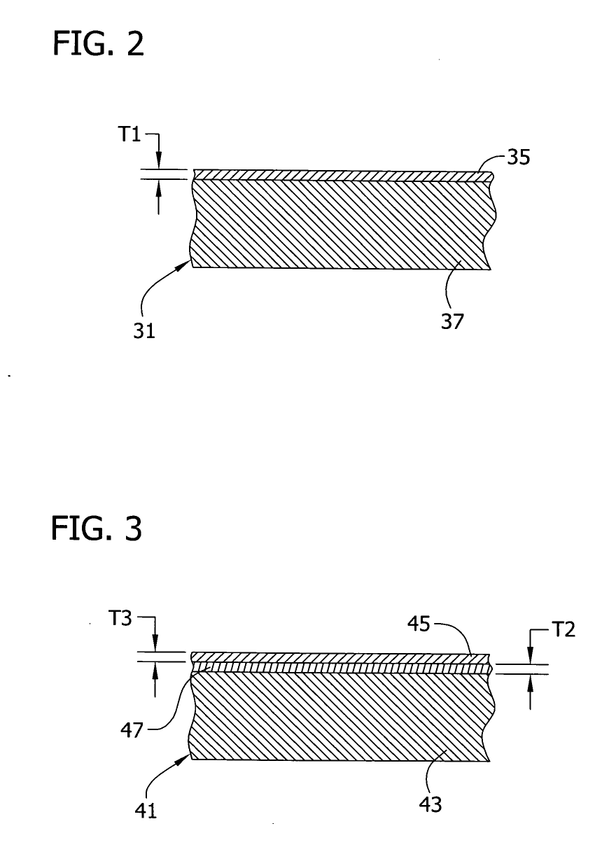

The crystal puller 1 of the present invention utilizes at least one component, a representative component generally indicated at 31 in FIG. 2, in the hot zone of the lower housing 3 that has a protective coating 35 of silicon nitride which covers the component. It will be understood that the component 31 may be all of, any number of, any combination of the components (e.g., susceptor 13, heater 19, heat shield 21, heat reflectors, and insulation) located in the hot zone of the crystal puller 1 which are free from contact with molten silicon in the puller. A partial cross-section of the representative hot zone component 31 is shown in FIG. 2. The component 3 includes a graphite layer 37 with the protective layer 35 of silicon nitride coating the graphite layer. The protective layer 35 of silicon nitride has a thickness T1 generally between about 25 micrometers and about 100 micrometers, preferably about 80 micrometers. The protective layer 35 of silicon nitride acts as a barrier that prevents the diffusion of iron (or other metal) vapor from the graphite layer 37 of the component 31.

The protective layer 35 of silicon nitride is grown on the graphite layer 37 of the component 31 by chemical vapor deposition (CVD) techniques known in the art such as ultra high vacuum chemical vapor deposition (UHVCVD) or atmospheric pressure chemical vapor deposition (APCVD). As are known, effective CVD procedures for producing a silicon nitride coating layer involve such operations as: (a) passing a mixture of silicon tetrachloride (SiCl₄) and ammonia (NH₃) over the substrate being coated in a carrier gas and heating the substrate to about 1,000 degrees C.; or (b) passing a mixture of silane (SiH₄) and ammonia (or alternatively, a mixture of ammonia and any cholorosilane such as SiH₂Cl₂ or SIHCl₃) over the substrate being coated which is heated to a temperature between about 800 degrees C. and 1,0000 degrees C. Other procedures using other gas mixtures and having other temperature ranges may also be suitable.

The silicon nitride layer 35 may be grown on top of the graphite layer 37 of the component 31 to a thickness T1 between about 25 micrometers and 100 micrometers. The silicon nitride layer 35 can be grown to enclose or cover the entirety of the component 31, or may be limited only to a portion thereof. However, it is preferable to grow the silicon layer 35 such that it entirely covers the underlying graphite layer 37 to provide maximum protection against crystal contamination by the diffusion of metal vapor from the graphite.

The hot zone component 31 constructed of graphite and having a protective layer 35 of silicon nitride can be used in the crystal pulling apparatus 1 of the present invention and several single silicon crystals grown before the silicon nitride layer must be removed and replaced. In one embodiment, the component 31 is capable of use in the crystal puller 1 for growing in excess of about 125 silicon crystals before the effectiveness of the protective layer 35 diminishes.

FIG. 3 shows a hot zone component, generally indicated at 41, of a second embodiment of the present invention. The component 41 has a graphite layer 43, a protective layer of silicon nitride 45, and an intervening layer 47 between the graphite and the silicon nitride layer. The intervening layer 47 may be silicon carbide or glassy carbon and has a thickness T2 generally between about 75 and about 150 micrometers, e.g., about 125 micrometers. Hot zone components constructed of graphite and having a silicon carbide or glassy carbon coating are commercially available from Graphite Die Mold, Inc. of Durham, Conn. The intervening layer 47 acts as an additional protective layer that contains contaminants which out diffuse and are released from the graphite layer 43 during exposure to high temperatures in the crystal pulling apparatus 1. In this embodiment, the protective layer 45 of silicon nitride is grown directly on the intervening layer 47 rather than the graphite layer 43. It is understood that the protective layer 45 of silicon nitride can be grown by conventional CVD processes or by other known processes and may have a thickness T3 substantially similar to the thickness T1 of the protective layer 35 of the first embodiment. Further the intervening layer 47 may be materials other than silicon carbide and glassy carbon without departing from the scope of this invention.

### EXPERIMENT

In this Experiment, the level of iron contamination in sample silicon wafers was measured. This Experiment is a predictive experiment designed to simulate the environment of the crystal puller during the crystal pulling process and the results of the experiment will correlate generally with the heating of the graphite components in the crystal puller hot zone.

A horizontal tube furnace was used to heat three sample wafers. Two of the three sample wafers had three graphite samples mounted thereon. Each graphite sample was approximately 50 mm in diameter and approximately 12 mm thick. Sample 1 and Sample 2 comprise graphite coated with a 100 micrometers thick layer of silicon carbide. Sample 3 and Sample 4 comprise graphite coated with a first protective layer of silicon carbide being about 100 micrometers thick and a second protective layer of silicon being about 25 micrometers thick. Sample 5 and Sample 6 comprise graphite coated with a protective layer of silicon nitride with a thickness of approximately 0.18 to 0.24 micrometers. Each of the two sample wafers having graphite samples thereon had one graphite sample with each type of protective coating. That is, one sample wafer had Sample 1, 3, and 5 mounted thereon and another sample wafer had Sample 2, 4, and 6 mounted thereon. The third sample wafer was a control wafer that was free from graphite samples.

The three sample wafers were silicon wafers and the two wafers having graphite samples had a fused silica mask to separate the sample wafer from each test sample and prevent direct contact between the sample wafer and the sample. Three holes in the fused silica mask allowed the sample wafer to be exposed to gases generated from the respective samples mounted thereon. Each test stack consisted of a sample wafer for measuring the amount of iron transferred via diffusion and a graphite sample on top of the hole in the fused silica mask. The control sample wafer did not have a fused silica mask nor any graphite samples thereon.

The three sample wafers (two wafers with the graphite samples and one control wafer) were loaded in the furnace, heated to three different temperatures (800 degrees C., 950 degrees C., and 1100 degrees C.), and tested to measure the iron diffusivity from the graphite sample to the sample silicon wafer after heat treatment at each of the three temperatures. The samples were held at atmospheric pressure in the oven for a period of two hours at each heat treatment temperature during which a stream of argon gas was maintained in the oven over the wafers.

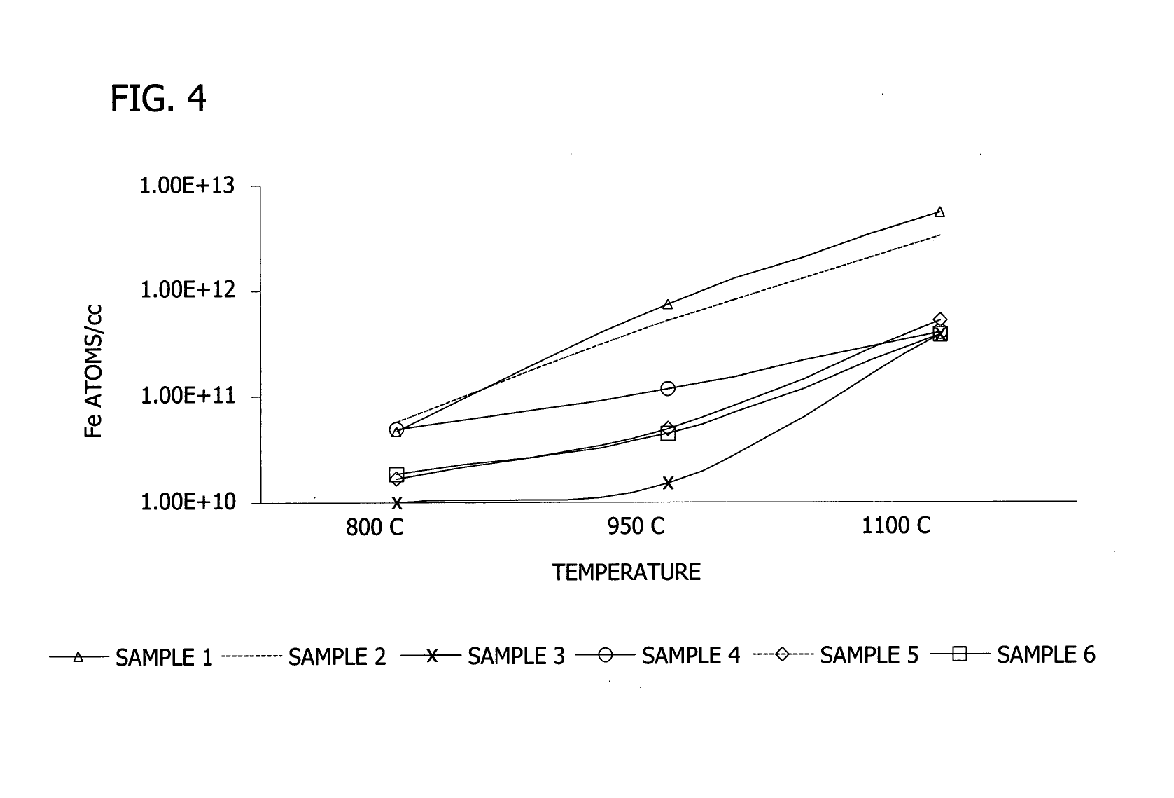

After each heat treatment, each sample wafer was tested for the amount of iron present therein using the surface photovoltaic technique described in ASTM Report F391-78. Several points across the wafer surface at each hole in the fused silicon mask on each of the two silicon sample wafers were tested for iron concentration and the average value of iron concentration across the sample wafer surface corresponding to the location of each graphite sample was recorded. As shown in FIG. 4, the resulting average iron concentration for each graphite sample was plotted as atoms per cubic centimeter versus absolute temperature.

FIG. 4 and Table 1 show a summary of the data from the experiment. At the three heat treatment temperatures, Samples 5 and 6 which included a protective coating of silicon nitride diffused less iron from the graphite samples to the silicon sample wafer than Samples 1 and 2 having a protective layer of silicon carbide. Also, the amount of iron diffused from Samples 5 and 6 was less than the amount of iron diffused from Sample 4 having a first protective layer of silicon carbide and a second protective layer of silicon at all heat treatment temperatures.

TABLE 1
Iron Concentration Results (Fe atoms/cc)

| | Temperature | Temperature | Temperature |
|---|---|---|---|
| | 800 C. | 950 C. | 1100 C. |
| Sample 1 | 4.69E+10 | 7.25E+11 | 5.49E+12 |
| Sample 2 | 5.66E+10 | 5.27E+11 | 3.21E+12 |
| Sample 3 | 1.01E+10 | 1.50E+10 | 3.71E+11 |
| Sample 4 | 4.82E+10 | 1.16E+11 | 3.97E+11 |
| Sample 5 | 1.71E+10 | 5.00E+10 | 5.08E+11 |
| Sample 6 | 1.86E+10 | 4.32E+10 | 3.84E+11 |

When introducing elements of the present invention or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that several objects of the invention are achieved and other advantageous results attained.

As various changes could be made in the above constructions without departing from the scope of the invention, it is intended that all matter contained in the above description or shown in the accompanying drawings shall be interpreted as illustrative and not in a limiting sense.

What is claimed is:

1. A crystal pulling apparatus for producing a silicon crystal having a reduced amount of metal contamination, the apparatus comprising:
a growth chamber; and
a component disposed within the growth chamber having a protective layer of silicon nitride for preventing metal contamination of the crystal.

2. The apparatus set forth in claim 1 wherein said component is selected from one of: a susceptor, a heater, a thermal shield, and a heat reflector.

3. The apparatus set forth in claim 1 wherein the protective layer on the component is at least about 25 micrometers thick.

4. The apparatus set forth in claim 1 wherein the protective layer on the component is between about 25 and about 100 micrometers thick.

5. The apparatus set forth in claim 1 wherein the protective layer on the component is formed by chemical vapor deposition.

6. The apparatus set forth in claim 1 wherein said component is made of graphite.

7. The apparatus set forth in claim 1 further comprising an intervening layer between the protective layer and the external surface of the component.

8. The apparatus set forth in claim 7 wherein the intervening layer is silicon carbide.

9. The apparatus set forth in claim 7 wherein the intervening layer is glassy carbon.

10. The apparatus set forth in claim 7 wherein the intervening layer has a thickness of at least about 125 micrometers.

11. The apparatus set forth in claim 1 wherein the protective layer has a thickness of at least about 25 micrometers.

12. The apparatus set forth in claim 1 wherein said component comprises a structure made of graphite and configured for reception in the crystal pulling apparatus in a location where the structure will not contact molten silicon.

13. A component for use in a single crystal forming apparatus, the component comprising a structure including graphite and configured for reception in the single crystal forming apparatus in a location where the structure will not contact molten silicon, and a protective layer of silicon nitride covering the structure to inhibit out diffusion of metal from the graphite during use in the single crystal forming apparatus.

14. The component set forth in claim 13 wherein the graphite contains no more than about 20 ppm total of iron, copper, nickel, and molybdenum.

15. The component set forth in claim 13 wherein the graphite contains no more than about 5 ppm total of iron, copper, nickel, and molybdenum.

16. The component set forth in claim 13 wherein the component is selected from one of a susceptor, a heater, a thermal shield and a heat reflector.

17. The component set forth in claim 13 wherein said single crystal forming apparatus comprises a crucible and said component is not the crucible.

18. The component set forth in claim 13 wherein the component comprises an intervening layer between the external surface of the graphite and the protective layer.

19. The component set forth in claim 18 wherein the intervening layer is silicon carbide.

20. The component set forth in claim 19 wherein the intervening layer is glassy carbon.
